(19) United States
(12) Patent Application Publication
(10) Pub. No.: US 2016/0086811 A1
(43) Pub. Date: Mar. 24, 2016

(54) VERTICAL NO-SPIN PROCESS CHAMBER

(71) Applicant: BEIJING SEVENSTAR ELECTRONICS CO., LTD., Beijing (CN)

(72) Inventors: Bruce Mackedanz, Cologne, MN (US); Sally-Ann Henry, Chaska, MN (US); Don C. Burkman, Osceola, WI (US); Charlie A. Peterson, Waconia, MN (US); Cary M. Ley, Andover, MN (US)

(21) Appl. No.: 14/957,154

(22) Filed: Dec. 2, 2015

Related U.S. Application Data
(63) Continuation of application No. 14/893,752, filed on Nov. 24, 2015.
(60) Provisional application No. 61/839,602, filed on Jun. 26, 2013.

(51) Int. Cl. H01L 21/306; H01L 21/02

(52) U.S. Cl. CPC H01L 21/30604; H01L 21/02057

(57) ABSTRACT

A processing chamber includes a base, a cover, and grippers. The base includes a body, a mating surface, an inner zone cavity extending into the body, a divider substantially surrounding the inner zone cavity, and an outer zone cavity extending into the body and substantially surrounding the divider. The cover includes a mating surface that contacts the body mating surface when the processing chamber is closed. The grippers hold the wafer in the inner zone cavity when the processing chamber is closed.

### BACKGROUND

The present invention relates to wafer processing, and, more particularly, to wafer processing in a closed immersion processing chamber.

During the fabrication of integrated circuits, a relatively large silicon substrate (also called a wafer) undergoes many individual processing steps to form many individual integrated circuits on its surface. There can be many types of steps used to form these integrated circuits, including masking, etching, deposition, diffusion, ion implantation, and polishing, among many others. Often, the wafer must be cleaned between the steps. The cleaning steps help ensure that the integrated circuits will be free of contamination that could cause harmful defects in the delicate structures of the integrated circuits. Due to the critical requirements of cleanliness for the wafer surfaces, the wafer is kept in clean room conditions and often with automated handling and processing through these many steps. As the technology level of the device structures and processes continues to advance, it is more common for the wafers to be processed on an individual (one by one) basis. This is especially true for the large substrates that are currently 300 mm (11.8 inches) in diameter and also may be true for the next proposed size of 450 mm (17.7 inches). Since the wet chemical processing steps are designed to reduce the contamination level to infinitesimal levels, extreme care must be taken in the design of the system used for processing. The chemicals and gases that come in contact with the wafer are likewise ultra clean and all materials used are designed to minimize any contamination.

While the size of the substrates is increasing, the size of the device structures of the integrated circuits is shrinking. This trend requires greater precision with respect to the fabrication and cleaning of the integrated circuits. More specifically, the wet chemicals that are involved in the formation of the device structures and the cleaning must be applied uniformly to the wafer. Cleaning can be enhanced by agitation of the cleaning agents while in contact with the wafer which assists the chemistries to remove particulate matter. At the same time, it is necessary to remove any contaminants which may be present while assuring that the sensitive, high-aspect ratio structures of the device are not harmed. In addition, any static charge should be minimized since it can attract particles to the surface and can directly harm the device's electrical performance. Because movement of the wafer and its support structure gives rise to triboelectric charge, spinning the wafer has been shown to generate significant charge. Therefore, it is difficult to properly clean a wafer without damaging the features thereon. In addition, the cleaning agents used can be very expensive due to their ultra clean nature. While using a large volume of cleaning agents can be beneficial for cleaning, it can be very wasteful and cost prohibitive.

### SUMMARY

According to one embodiment of the present invention, a processing chamber includes a base, a cover, and grippers. The base includes a body, a mating surface, an inner zone cavity extending into the body, a divider substantially surrounding the inner zone cavity, and an outer zone cavity extending into the body and substantially surrounding the divider. The cover includes a mating surface that contacts the body mating surface when the processing chamber is closed. The grippers hold the wafer in the inner zone cavity when the processing chamber is closed.

In another embodiment, a processing chamber includes a base and a cover. The base includes a body, a mating surface, and an inner zone cavity extending into the body. The cover includes a mating surface that contacts the body mating surface when the processing chamber is closed, and the cover includes grippers that extend from the mating surface into the inner zone cavity when the processing chamber is closed.

In another embodiment, a method of processing a wafer includes loading the wafer into an inner zone of a processing chamber and locking it in a stationary position. The wafer is immersed in a processing chemical in an inner zone of a processing chamber by flowing the processing chemical into the inner zone while the wafer remains stationary. The processing chemical also flows into an outer zone that substantially surrounds the inner zone and exits from the processing chamber.

In another embodiment, a method of exchanging liquid in a processing chamber includes providing the processing chamber containing a liquid and a wafer located in an inner zone. Another liquid flows into an inner zone and an outer zone that substantially surrounds the inner zone, and flows through nozzles that connect the inner and outer zones. The liquid exits the processing chamber from the inner zone through one port and from the outer zone through another port.

In another embodiment, a method of exchanging fluid in a processing chamber includes providing the processing chamber containing a fluid and a wafer located in an inner zone. A liquid flows into the inner and immerses the wafer, and the fluid exits from the inner zone through a port. The liquid flows into an outer zone that substantially surrounds the inner zone, and the fluid exits from the outer zone through another port. The liquid continues to flow into the inner zone and exits from the outer zone.

### BRIEF DESCRIPTION OF THE DRAWINGS

FIG. 1 is a perspective view showing an open processing chamber with a wafer held by an end effector between a base and a cover of the processing chamber.

FIG. 2 is a front elevation view of the base of the processing chamber.

FIG. 3 is a front elevation view of the cover of the processing chamber.

FIG. 4 is a side cross-section view of a loaded, closed processing chamber along line 4-4 in FIG. 1.

FIG. 5 is a flow diagram of a method of performing a processing operation in the processing chamber.

FIG. 6A is a cross-section view of the processing chamber along line 6-6 in FIG. 1 during operation.

FIG. 6B is a cross-section view of the processing chamber along line 6-6 in FIG. 1 during operation.

### DETAILED DESCRIPTION

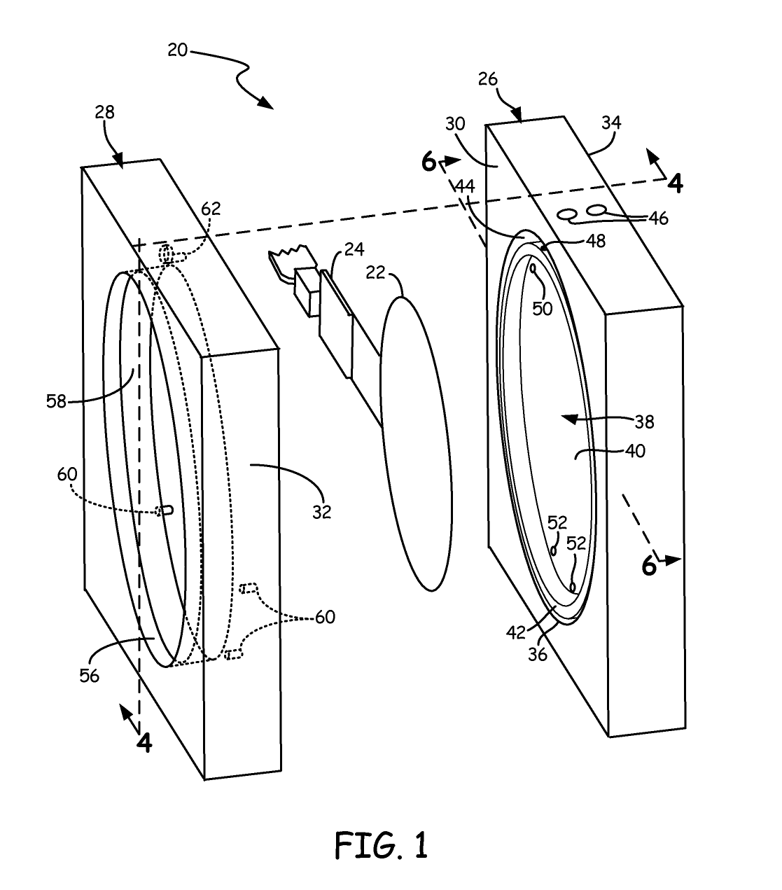

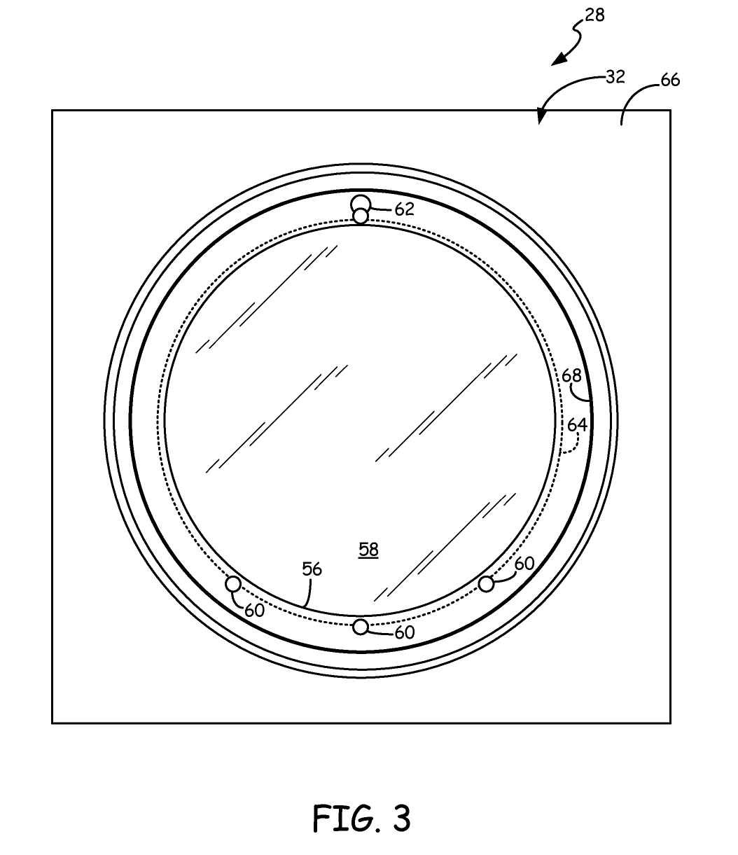

In FIG. 1, an exploded perspective view of processing chamber 20, wafer 22, and end effector 24 is shown. Processing chamber 20 includes chamber base 26 and chamber cover 28, and, in the illustrated embodiment, base 26 and cover 28 are spaced apart from each other with end effector 24 holding wafer 22 in between them. As will be explained in greater detail with respect to FIG. 3, this configuration would occur during the loading or unloading of wafer 22 into or out of chamber 20. When chamber 20 is closed, mating surface 30 of base 26 is in contact with mating surface 32 of cover 28.

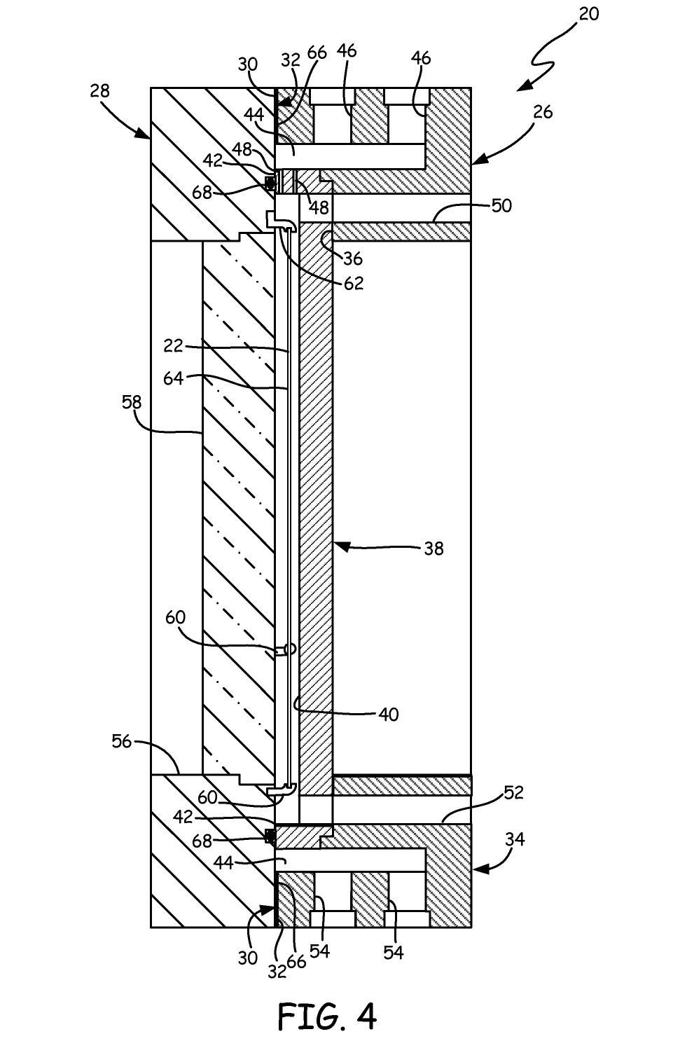

In the illustrated embodiment, base 26 includes a solid base body 34 and basin 36. Basin 36 is a cylindrical recess into mating surface 30 of base body 34 into which plate 38 is positioned. Plate 38 includes inner zone 40 and divider 42. When chamber 20 is loaded and closed (as shown in FIG. 4), wafer 22 resides in inner zone 40. Thereby, inner zone 40 is a cylindrical feature that extends into plate 38 and is slightly larger in diameter than wafer 22. Plate 38 also includes divider 42, which is a solid ring that sits flush with mating surface 30 when plate 38 is attached to body 34. Divider 42 substantially surrounds inner zone 40 and defines outer zone 44. More specifically, outer zone 44 is bordered by the outer side of divider 42 and the inner and front sides of basin 36. Therefore, outer zone 44 is an annular cavity that is radially outward from and substantially surrounds inner zone 40.

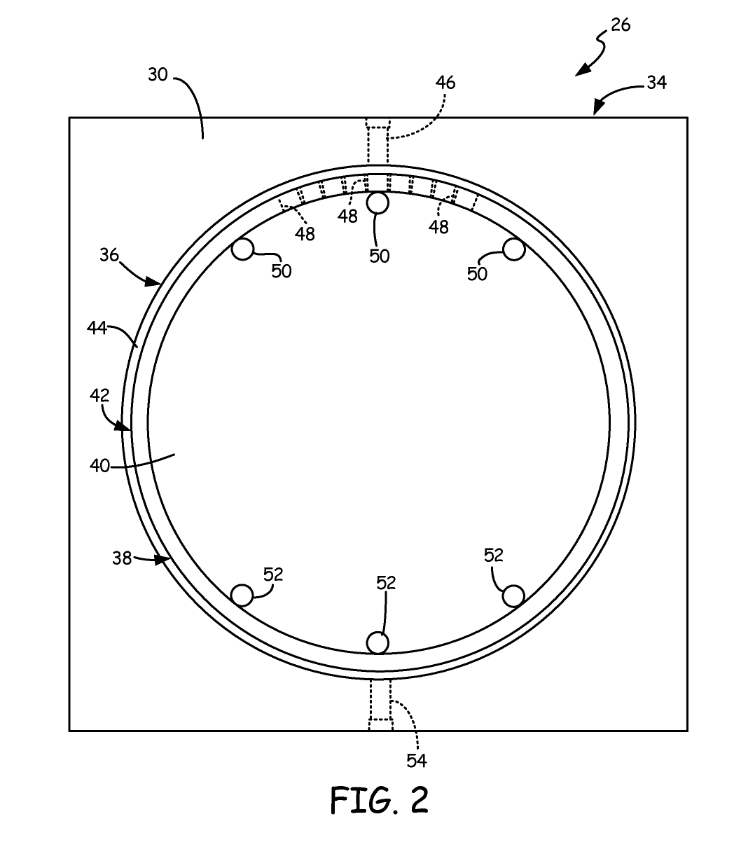

As will be explained in greater detail with respect to FIGS. 2 and 4, there are several groups of apertures in body 34 and plate 38 that function as fluid connections. Although not all of the apertures are visible in FIG. 1, these apertures include top ports 46, nozzles 48, upper ports 50, lower ports 52, and bottom ports 54 (shown in FIG. 2).

In the illustrated embodiment, cover 28 is a solid body that includes bore 56, window 58, stationary grippers 60, and movable gripper 62. Bore 56 is a cylindrical cavity that extends through cover 28. Window 58, having a cylindrical shape, is fixed within bore 56 and sits flush with mating surface 32. Stationary grippers 60 and movable gripper 62 are positioned in a circular pattern around window 58. Stationary grippers 60 are attached to cover 28 near the bottom of cover 28. Movable gripper 62 is attached to cover 28 near the top of cover 28, and movable gripper 62 rotates to hold wafer 22. More specifically, movable gripper 62 is rotated upward so that end effector 24 can place wafer 22 on stationary gripper 60. Once wafer 22 is in position, movable gripper 62 rotates downward to lock wafer 22 in a stationary position. This permits end effector 24 to release wafer 22 and retract so that chamber 20 can close.

The components and configuration of processing chamber 20 as shown in FIG. 1 allow for wafer 22 to be processed using fluids in a controlled, closed environment while remaining stationary. Such a controlled environment can be regulated to have, for example, a particular temperature, pressure, and/or a low oxygen concentration. Processing can comprise one or more types of processes such as, but not limited to, residue removal, photoresist removal, metallic or dielectric layer removal, cleaning, or wet etching.

Depicted in FIG. 1 is one embodiment of the present invention, to which there are alternative embodiments. For example, grippers 60, 62 can extend from inner zone 40 of base 26. For another example, bore 56 and window 58 can be absent from cover 28. For a further example, bore 56 can include a sonic transducer for emitting ultrasonic or megasonic waves in place of window 58.

Furthermore, in the illustrated embodiment of FIG. 1, wafer 22 is a substantially circular silicon wafer substrate. However, wafer 22 can be, but is not limited to, a solar cell substrate or a germanium wafer. In addition, wafer 22 can have another shape, including, but not limited to, that of a rectangle. In such an embodiment, the interior features of chamber 20, such as the shape of inner zone 40, divider 42, and outer zone 44, may need to be changed in order to correspond to the shape of wafer 22. Wafer 22 can have an active side (i.e. a side with device features on it), and the active side can face either base 26 or cover 28.

In FIG. 2, a front elevation view of base 26 of processing chamber 20 is shown. In the illustrated embodiment, base 26 is comprised of a chemical-resistant material, such as polytetrafluoroethylene (PTFE).

As stated previously, base 26 has two main cavities (inner zone 40 and outer zone 44) with a plurality of fluid apertures. More specifically, base body 34 includes two top ports 46 (with one behind the other) that connect with outer zone 44 at the top of body 34. Body 34 also includes two bottom ports 54 (with one behind the other) that connect with outer zone 44 at the bottom of body 34. Top ports 46 and bottom ports 54 allow for fluid to flow into and out of chamber 20 at outer zone 44.

Furthermore, base 26 has a plurality of upper ports 50 near the top of plate 38 that pass through both body 34 and plate 38. Base 26 also has a plurality of lower ports 52 near the bottom of plate 38 that pass through both body 34 and plate 38. Upper ports 50 and lower ports 52 allow for fluid to flow into and out of chamber 20 at inner zone 40.

In addition, there are two rows of nozzles 48 (with one behind the other) at the top of plate 38. The plurality of nozzles 48 pass through divider 42, fluidly connecting inner zone 40 and outer zone 44. In the illustrated embodiment each nozzle 48 is a tapered slot, the size of which decreases as each nozzle extends radially inwardly from the outer side of divider 42.

The components and configuration of base 26 as shown in FIG. 2 allow for fluid to flow into, through, and out of chamber 20. More specifically, fluid can flow into, through, and out of outer zone 44 and inner zone 40 (where wafer 22 resides, as shown in FIG. 4).

Depicted in FIG. 2 is one embodiment of the present invention, to which there are alternative embodiments. For example, in addition, plate 38 can be comprised of a chemical-resistant, transparent or translucent material that transmits light, such as sapphire or perfluoroalkoxy (PFA). For another example, there can be more or less apertures in each group of ports 46, 50, 52, 54 or nozzles 48. Also, the apertures can extend in alternate orientations or have alternate cross-sectional shapes. As a more specific example, each nozzle 48 can be oriented substantially vertically, have a circular cross-section, and/or have a constantly sized cross-section. Moreover, nozzles 48 can have differing sizes and can be arranged with larger nozzles 48 toward the top center of plate 38 and smaller nozzles 48 toward the edges of the array of nozzles 48.

In FIG. 3, a front elevation view of cover 28 of processing chamber 20 is shown. In the illustrated embodiment, cover 28 is comprised of a chemical-resistant material, such as PTFE.

As stated previously, cover 28 holds wafer 22 when chamber 20 is loaded (as shown in FIG. 4). In the illustrated embodiment wafer 22 is absent, although the location where wafer 22 would reside is indicated by wafer position 64. Wafer position 64 corresponds to the shape of wafer 22 (shown in FIG. 1) and is bounded by stationary grippers 60 and movable gripper 62 (which is shown in the holding position). In order to load wafer 22 into wafer position 64, movable gripper 62 rotates upward (either clockwise or counterclockwise) away from wafer position 64. In order to lock wafer 22 into wafer position 64 after wafer 22 is loaded, movable gripper 62 is rotated toward the bottom center position until movable gripper 62 contacts the edge of wafer 22.

Cover 28 also includes flat seal 66 and ring seal 68 on mating surface 32 that interface with mating surface 30 of base 26 (shown in FIG. 1). In the illustrated embodiment, seals 66, 68 comprise a chemical-resistant, elastomeric material, such as a perfluoro-elastomer. Seals 66, 68 will be discussed in more detail with respect to FIG. 4.

As stated previously, cover 28 includes window 58. In the illustrated embodiment, window 58 is comprised of a chemical-resistant, transparent or translucent material that transmits light, such as visible light or other electromagnetic radiation with higher or lower wavelengths than visible light. Such materials can include sapphire or PFA.

The components and configuration of cover 28 as shown in FIG. 3 allow for wafer 22 to be held in chamber 20 (shown in FIG. 1). In addition, cover 28 seals against base 26 when chamber 20 is closed, and the interior of chamber 20 can be viewed through window 58.

Depicted in FIG. 3 is one embodiment of the present invention, to which there are alternative embodiments. For example, movable gripper 62 can slide upwards and downwards to release and to hold wafer 22, respectively. For another example, window 58 can be transparent to a different wavelength of light other than visible. Such an embodiment can be beneficial when using a machine vision system or other types of optical sensors.

In FIG. 4, a side cross-section view of a loaded, closed processing chamber 20 is shown along line 4-4 in FIG. 1. The components and configuration of the parts of the illustrated chamber 20 are the same as present in FIGS. 1-3, with additional features being shown in FIG. 4. For example, wafer 22 is held in wafer position 64 that is spaced outwardly apart from mating surface 32 of cover 28. In this manner, wafer 22 is positioned in inner zone 40 of base 26. For another example, flat seal 66 and ring seal 68 are shown engaging base 26, sealing the interior of chamber 20 (including inner zone 40 and outer zone 44) from leakage between base 26 and cover 28.

In addition, both top ports 46, both bottom ports 54, and both rows of nozzles 48 are visible in FIG. 4. Top ports 46, upper ports 50, lower ports 52, and bottom ports 54 are configured to receive and expel liquids and gasses from chamber 20. The source and/or destination for these fluids can be a chemical distribution system (not shown). Each port 46, 50, 52, 54 is controlled by a valve (not shown) that can be opened, closed, and throttled as necessary to control flow. As process time equates to throughput (in wafers per hour), a vacuum source (not shown) can be employed to assist with flow through ports 46, 50, 52, 54, which shortens the time to fill and/or evacuate chamber 20.

In the illustrated embodiment, upper ports 50 and lower ports 52 are directly connected to inner zone 40. Top ports 46 and bottom ports 54 are directly connected to outer zone 44. As stated previously, nozzles 48 connect outer zone 44 with inner zone 40 through divider 42. In the illustrated embodiment, one row of nozzles 48 is on one side of wafer 22 and the other row of nozzles 48 is on the other side of wafer 22 to promote flow along both sides of wafer 22. Alternatively, there can be a single row of nozzles 48, and, in such an embodiment, nozzles 48 are oriented towards the outer edge of wafer 22.

As introduced previously, mating surface 32 of cover 28 includes flat seal 66 to generally seal chamber 20. Flat seal 66 extends around the entire outer portion of mating surface 32 to prevent leakage from the inside of chamber 20 to the exterior environment between cover 28 and base 26. Mating surface 32 also includes ring seal 68 which interfaces with divider 42. Ring seal 68 prevents leakage between inner zone 40 and outer zone 44 between cover 28 and base 26 (although ring seal 68 does not prevent flow through nozzles 48). Flat seal 66 and ring seal 68 are comprised of a chemical-resistant elastomeric material. In an alternate embodiment, flat seal 66 can be an o-ring seal similar to ring seal 68 that extends around outer zone 44. In addition, flat seal 66 and/or ring seal 68 can be configured with a different cross-sectional shape that still provides a sealing effect and additionally can be fully rinsed and cleaned to avoid contamination.

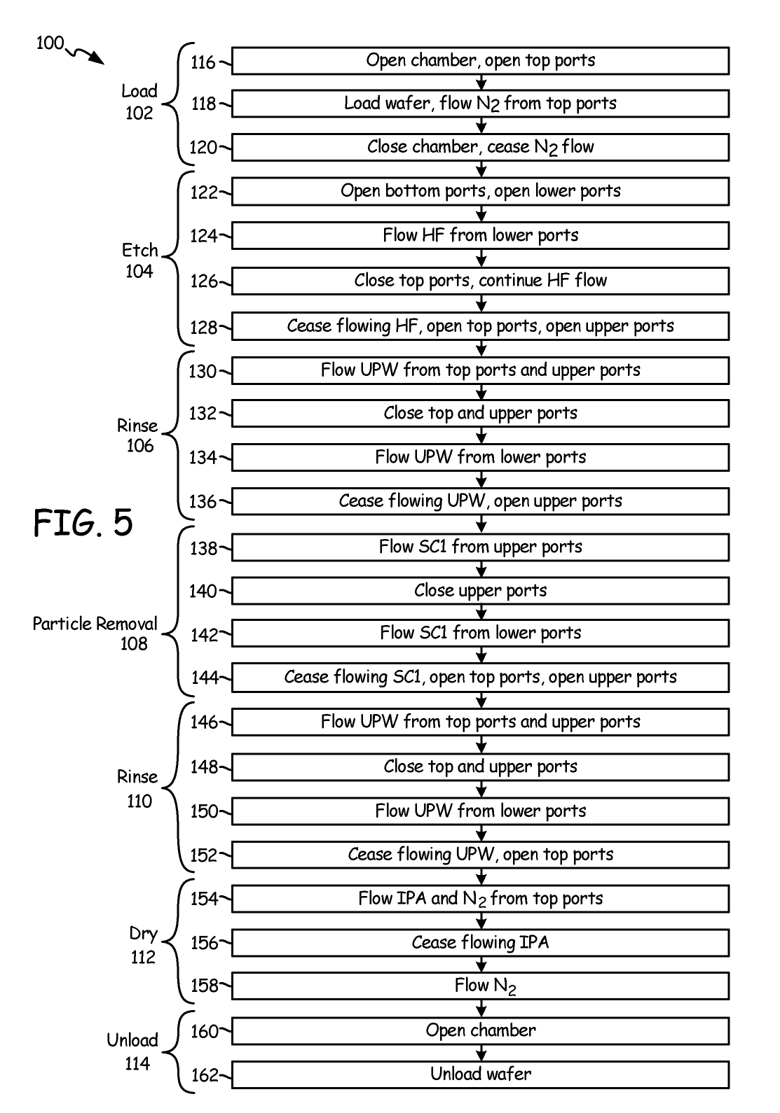

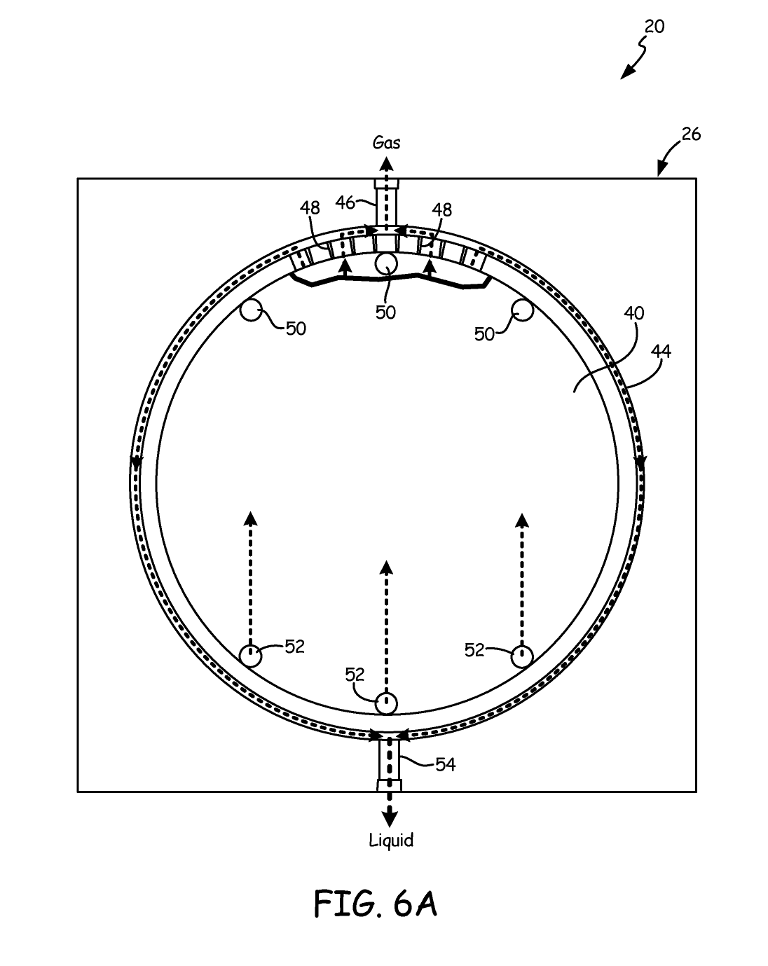

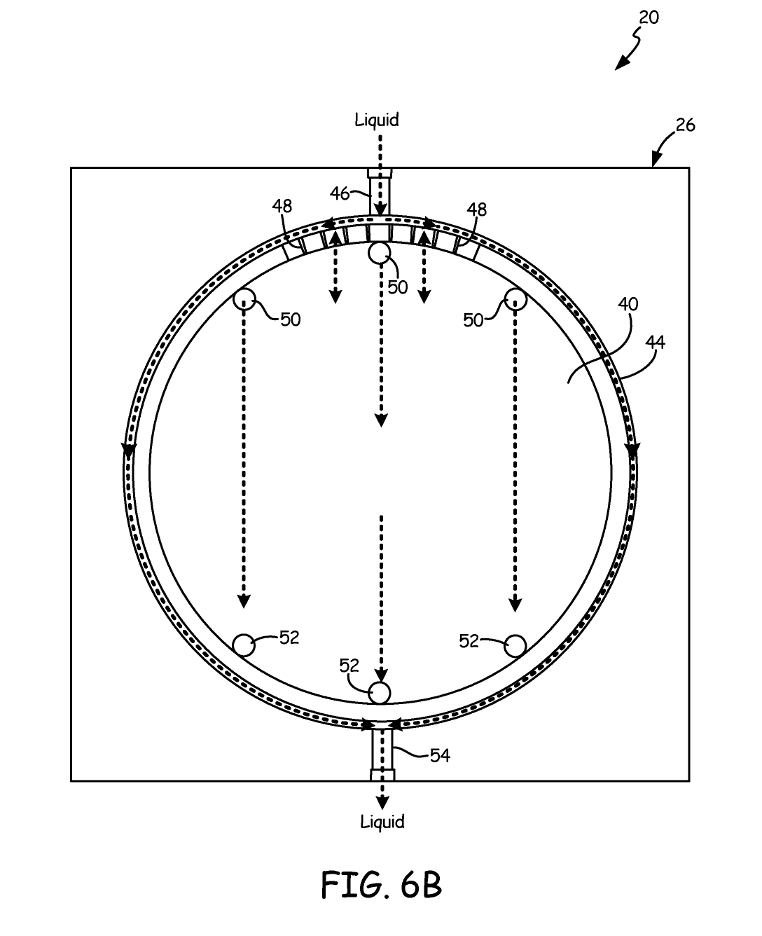

During operation of chamber 20, fluid can flow into and/or out of any of ports 46, 50, 52, 54. More specifically, fluid can flow into one of ports 46, 50, 52, 54 as long as the fluid already in chamber 20 flows out of another of ports 46, 50, 52, 54. Thereby, one fluid inside chamber 20 can be exchanged with another fluid and/or one fluid can be circulated within chamber 20. Some examples of different fluids and flow patterns will be discussed later with respect to FIGS. 5-6B.

The components and configuration of processing chamber 20 as shown in FIG. 4 provides a closed environment in which to process wafer 22 without moving wafer 22. This is because ports 46, 50, 52, 54 and nozzles 48 provide the necessary fluid flow within chamber 20.

In FIG. 5, a flow diagram of method 100 of performing a processing operation in processing chamber 20 is shown. Method 100 has been divided into processes that are further divided into individual steps. More specifically, method 100 includes loading process 102, etching process 104, first rinsing process 106, particle removing process 108, second rinsing process 110, drying process 112, and unloading process 114. It is assumed that at the beginning of method 100, the valves (not shown) that control flow through ports 46, 50, 52, and 54 are closed and need to be opened in order to allow flow therethrough, respectfully.

Loading process 102 includes steps 116, 118, and 120. At step 116, chamber 20 is opened and top ports 46 are opened. At step 118, end effector 24 transports wafer 22 to wafer position 64 and gaseous nitrogen is flowed from top ports 46. After movable gripper 62 locks wafer 22 into place and end effector 24 has retracted, at step 120, chamber 20 closes by moving cover 28 towards base 26 until mating surfaces 30, 32 contact each other. Also at step 120, nitrogen flow ceases.

Etching process 104 includes steps 122, 124, 126, and 128. At step 122, lower ports 52 and bottom ports 54 are opened. At step 124, processing chemical (in the illustrated embodiment, etching liquid) is flowed from lower ports 52, and the existing nitrogen gas inside chamber 20 exits through top ports 46. Flooding inner zone 40 with etching liquid essentially starts a chemical reaction between the etching liquid and wafer 22. At step 126, once wafer 22 is immersed in etching liquid, top ports 46 are closed and etching liquid continues to flow in order to continue the reaction. As will be discussed in greater detail with respect to FIG. 6A, the excess etching liquid will pass up through nozzles 48, down and around outer zone 44, and will exit chamber 20 through bottom ports 54. At step 128, etching liquid stops flowing, and top ports 46 and upper ports 50 are opened. The etching liquid used in etching process 104 can be, but is not limited to, dilute hydrofluoric acid or buffered oxide etch (a common etching liquid that is an aqueous mixture of ammonium fluoride and hydrofluoric acid).

First rinsing process 106 includes steps 130, 132, 134, and 136. At step 130, ultra pure water (UPW) is flowed from top ports 46 and upper ports 50 into inner zone 40 and outer zone 44. This displaces substantially all of the etching liquid in chamber 20 (which exits via lower ports 52 and bottom ports 54), essentially stopping the reaction between the etching liquid and wafer 22. At step 132, top ports 46 and upper ports 50 are closed. At step 134, UPW is flowed from lower ports 52 to continue to rinse wafer 22. The UPW flows up through nozzles 48, down and around outer zone 44, and will exit chamber 20 through bottom ports 54. At step 136, UPW flow is ceased, and upper ports 50 are opened.

Particle removing process 108 includes steps 138, 140, 142, and 144. At step 138, a particle removing liquid is flowed from upper ports 50 into inner zone 40. This displaces substantially all of the UPW in chamber 20 (which exits via lower ports 52 and bottom ports 54), and as the particle removing liquid continues to flow, it also exits chamber 20 through lower ports 52 and bottom ports 54. At step 140, upper ports 50 are closed. At step 142, the liquid is flowed from lower ports 52 to continue removing particles. This liquid flows up through nozzles 48, down and around outer zone 44, and will exit through bottom ports 54. At step 144, liquid flow is ceased, and top ports 46 and upper ports 50 are opened. The particle removing liquid used in particle removing process 108 can be, but is not limited to, SC1 (a common cleaning liquid that is an aqueous mixture of ammonium hydroxide and hydrogen peroxide).

Second rinsing process 110 includes steps 146, 148, 150 and 152. At step 146, UPW is flowed from top ports 46 and upper ports 50 into inner zone 40 and outer zone 44. This displaces substantially all of the particle removing liquid in chamber 20 (which exits via lower ports 52 and bottom ports 54). As UPW continues flowing, it also exits chamber 20 through lower ports 52 and bottom ports 54. At step 148, top ports 46 and upper ports 50 are closed. At step 150, UPW is flowed from lower ports 52 to continue to rinse wafer 22. The UPW flows up through nozzles 48, down and around outer zone 44, and will exit chamber 20 through bottom ports 54. At step 152, UPW flow is ceased, and top ports 46 are opened.

Drying process 112 includes steps 154, 156, and 158. At step 154, a drying fluid flows from top ports 46 and the UPW in chamber 20 exits chamber 20 through lower ports 52 and bottom ports 54 in a controlled fashion. The drying fluid has a low surface tension that allows for the sheeting off of UPW from the surfaces of wafer 22 at a controlled linear rate of, for example, three to five millimeters per second. The control of this process is accomplished by the valve (not shown) that controls flow through bottom ports 54. The drying fluid used in drying process 112 can be, but is not limited to, a mixture of gaseous nitrogen and isopropyl alcohol (in liquid or vapor form). At step 156, isopropyl alcohol flow is ceased although gaseous nitrogen is still flowing. At step 158, gaseous nitrogen is flowed in chamber 20 to clear out any remaining isopropyl alcohol.

Unloading process 114 includes steps 160 and 162. At step 160, chamber 20 opened by cover 28 separating from base 26. At step 162, end effector 24 grabs onto wafer 22, movable gripper 62 releases wafer 22, and end effector 24 and wafer 22 retract from chamber 20. At this time, method 100 can restart at step 118, otherwise nitrogen flow can be ceased and chamber 20 can be closed if another wafer 22 will not be loaded.

The processes and steps of method 100 as shown in FIG. 5 allow for wafer 22 to be etched and cleaned in one continuous process. In addition, wafer 22 does not need to move with respect to chamber 20 during method 100.

Depicted in FIG. 5 is one embodiment of the present invention, to which there are alternative embodiments. For example, method 100 can be only an etching process. In such an embodiment, steps 138, 140, 142, 144, 146, and 152 would not be necessary. For another example, method 100 can be only a cleaning process. In such an embodiment, step 122 would include opening top ports 46 and upper ports 50 and steps 124, 126, 128, 130, and 132 would not be necessary. For a further example, method 100 can use alternative processing chemicals, including, but not limited to, SC2 (a common cleaning liquid that is an aqueous mixture of hydrochloric acid and hydrogen peroxide). For yet another example, additional processes can be added to method 100, such as a metal removal process after second rinsing process 110. Such an additional process can also have an additional third rinsing process afterward.

In FIG. 6A, a cross-section view of processing chamber 20 along line 6-6 in FIG. 1 during operation is shown. More specifically, depicted in FIG. 6A can be step 124 of etching process 104, step 134 of first rinsing process 106, or step 150 of second rinsing process 110. As stated previously, during step 124, upper ports 50 are closed and etching liquid is flowed from lower ports 52. The liquid evacuates the gas in chamber 20 out through top ports 46, while the liquid itself travels upward through inner zone 40. Once the liquid level has reached sufficient height, the liquid will flow through nozzles 48, down and around outer zone 44, and exit chamber 20 through bottom ports 54.

In the illustrated embodiment, the liquid flow rate through lower ports 52 fills inner zone 40 rapidly enough to completely immerse wafer 22 (shown in FIG. 4) in four seconds. This immersion essentially starts the chemical reaction between the liquid and wafer 22 at the uppermost point of wafer 22 within four seconds of the start of the reaction at the lowermost point of wafer 22. Preferably, wafer 22 can be immersed in two seconds. More preferably, wafer 22 can be immersed in one second.

In FIG. 6B, a cross-section view of processing chamber 20 along line 6-6 in FIG. 1 during operation is shown. More specifically, depicted in FIG. 6B can be steps 130, 146 of rinsing processes 106, 110, respectively. As stated previously, at steps 130 and 146, liquid (i.e. UPW) is flowed from top ports 46 and upper ports 50 into inner zone 40 and outer zone 44. (Which may cause liquid to flow through nozzles 48, and the direction of such flow depends on the relative flow rates from ports 46, 50, among other factors.) This displaces the existing liquid in chamber 20 (which exits via lower ports 52 and bottom ports 54). As the liquid continues flowing, it also exits chamber 20 through lower ports 52 and bottom ports 54.

In the illustrated embodiment, the liquid flow rate through upper ports 50 fills inner zone 40 rapidly enough to completely immerse wafer 22 (shown in FIG. 4) in four seconds. With respect to step 130, this immersion in UPW essentially stops the chemical reaction between the etching liquid and wafer 22 at the uppermost point of wafer 22 within four seconds of the start of the reaction at the lowermost point of wafer 22. Preferably, wafer 22 can be immersed in two seconds. More preferably, wafer 22 can be immersed in one second.

It should be recognized that the present invention provides numerous benefits and advantages. For example, wafer 22 remains stationary during processing, which prevents static charge build-up, structural damage due to kinetic force, and particle generation. In addition, processing chamber 20 has very few moving parts, which increases reliability. Chamber 20 also provides a relatively small closed volume inside of which the environment can be controlled. This is beneficial to preserving the surface integrity of wafer 22 and allows for fast filling and draining of chamber 20.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A method of processing a wafer, the method comprising:
loading the wafer into an inner zone of a processing chamber, the wafer being locked in a stationary position;
immersing the wafer in a processing chemical by flowing the processing chemical into the inner zone while the wafer remains stationary;
flowing the processing chemical into an outer zone of the processing chamber that substantially surrounds the inner zone; and
exiting the processing chemical from the processing chamber.

2. The method of claim 1, wherein the processing chemical is an etching liquid.

3. The method of claim 1, wherein immersing the wafer starts a chemical reaction between the processing chemical and the wafer.

4. The method of claim 1, wherein the wafer is immersed in the processing chemical in less than four seconds.

5. The method of claim 1, wherein the wafer is immersed in the processing chemical in less than two seconds.

6. The method of claim 1, wherein the wafer is immersed in the processing chemical in less than one second.

7. The method of claim 1, further comprising:
immersing the wafer in water by flowing the water into the inner zone and the outer zone; and
exiting substantially all of the processing chemical from the processing chamber.

8. The method of claim 7, further comprising:
immersing the wafer in a particle removing liquid by flowing the particle removing liquid into the inner zone and the outer zone; and
exiting substantially all of the water from the processing chamber.

9. The method of claim 8, further comprising:
immersing the wafer in a water by flowing the water into the inner zone and the outer zone; and
exiting substantially all of the particle removing liquid from the processing chamber.

10. The method of claim 9, further comprising:
immersing the wafer in a mixture of isopropyl alcohol and gaseous nitrogen by flowing the mixture into the outer zone, through a plurality of nozzles, into the inner zone; and
exiting substantially all of the water from the processing chamber to dry the wafer.

11. A method of exchanging liquid in a processing chamber, the method comprising:
providing the processing chamber containing a first liquid and a wafer located in an inner zone;
flowing a second liquid into an inner zone and into an outer zone of the processing chamber, the outer zone substantially surrounding the inner zone;
flowing the second liquid through a plurality of nozzles that fluidly connect the inner zone and the outer zone; and
exiting from the processing chamber the first liquid from the outer zone through a first port and from the inner zone through a second port.

12. The method of claim 11, wherein flowing the second liquid into the inner zone substantially fills the inner zone with the second liquid in less than four seconds.

13. The method of claim 11, wherein flowing the second liquid into the inner zone substantially fills the inner zone with the second liquid in less than two seconds.

14. The method of claim 11, wherein flowing the second liquid into the inner zone substantially fills the inner zone with the second liquid in less than one second.

15. The method of claim 11, wherein the first liquid comprises an etching liquid and the second liquid comprises water.

16. A method of exchanging fluid in a processing chamber, the method comprising:
providing the processing chamber containing a first fluid and a wafer located in an inner zone;
immersing the wafer located in an inner zone of a processing chamber in a liquid by flowing the liquid into the inner zone;
exiting a fluid from the inner zone through a first port;
flowing the liquid into an outer zone of the processing chamber that substantially surrounds the inner zone;
exiting the fluid from the outer zone through a second port; and
exiting the liquid from the outer zone by continuing to flow the liquid into the inner zone.

17. The method of claim 16, wherein immersing the wafer starts a chemical reaction between the liquid and the wafer.

18. The method of claim 16, wherein the wafer is immersed in the liquid in less than four seconds.

19. The method of claim 16, wherein the wafer is immersed in the liquid in less than two seconds.

20. The method of claim 16, wherein the wafer is immersed in the liquid in less than one second.

21. The method of claim 16, wherein the liquid comprises an etching liquid and the fluid comprises nitrogen gas.
